(19) United States
(12) Patent Application Publication
(10) Pub. No.: US 2007/0040262 A1
(43) Pub. Date: Feb. 22, 2007

(54) Flexible substrate capable of preventing lead thereon from fracturing

(75) Inventors: Min-O Huang, Jiangjyun Township (TW); Ming-Hsun Li, Chiayi City (TW)

Correspondence Address: THE LAW OFFICES OF ANDREW D. FORTNEY, PH.D., P.C., 401 W FALLBROOK AVE STE 204, FRESNO, CA, 93711-5835, US

(73) Assignees: ChipMos Technologies Inc.; ChipMos Technologies (Bermuda) LTD

(21) Appl. No.: 11/303,184

(22) Filed: Dec. 15, 2005

(30) Foreign Application Priority Data
Aug. 19, 2005 (TW) 094128292

(51) Int. Cl. H01L 23/52

(52) U.S. Cl. 257/692; 257/696; 257/773

(57) ABSTRACT

The invention discloses a flexible substrate including a flexible insulating film and a plurality of leads formed on an upper surface of the flexible insulating film. Each of the leads includes a first portion, a second portion, and a connection portion connecting the first portion and the second portion. The connection portion of at least one of the leads is designed as being crooked to provide a deformability to resist a tensile force once suffered by said one lead.

### BACKGROUND OF THE INVENTION

1. Field of the Invention

The present invention relates to a flexible substrate; and more particularly, the invention relates to a flexible substrate which can prevent the leads from breaking.

2. Description of the Prior Art

Please refer to FIG. 1A and FIG. 1B. FIG. 1A is a schematic diagram of a substrate 10 according to the prior art, and FIG. 1B is an enlarged view of the plurality of leads 14 shown in FIG. 1A. As shown in FIG. 1A, the substrate 10, according to the prior art, includes an insulating film 12 and a plurality of leads 14 formed on the insulating film 12. As shown in FIG. 1B, each of the leads 14 includes a first portion 140, a second portion 142, and a connection portion 144 connecting the first portion 140 and the second portion 142. The first portion 140 of each of the leads 14 is to be bonded to a die (not shown), and the second portion 142 of each of the leads 14 is to provide with a bonding for an external device (not shown). In the electronics industry nowadays, as the development of integrated circuit tends to focus on high efficiency and miniaturization, the packaging of semiconductor chips also gradually grows towards miniaturization. Accordingly, the width W₁ of the first portion 140 of each of the leads 14 is less than the width W₂ of the second portion 142 of each of the leads 14, as shown in FIG. 1B.

During the designing process of electronics products, when the first portion 140 of each of the leads 14 is pulled by a first force F₁, and the second portion 142 of each of the leads 14 is pulled by a second force F₂ opposite to the first force F₁, stress will concentrate on the connection portion 144a of one lead 14a of the leads 14 and will further cause fracture.

Accordingly, the present invention provides a flexible substrate to solve the problem mentioned above.

### SUMMARY OF THE INVENTION

A scope of the invention is to provide a flexible substrate which can prevent the leads from breaking. In addition, the connection of at least one of the leads is designed as crooked to prevent the leads from breaking.

According to a preferred embodiment, the flexible substrate of the invention includes a flexible insulating film and a plurality of leads. The flexible insulating film has an upper surface. The leads are formed on the upper surface of the flexible insulating film, and each of the leads includes a first portion, a second portion, and a connection portion connecting the first portion and the second portion. Furthermore, at least one of the leads exhibiting a crooked shape at the connection portion thereof to provide a deformability to resist a tensile force once suffered by said one lead.

The advantage and spirit of the invention may be understood by the following recitations together with the appended drawings.

### BRIEF DESCRIPTION OF THE APPENDED DRAWINGS

FIG. 1A is a schematic diagram of a substrate according to the prior art.

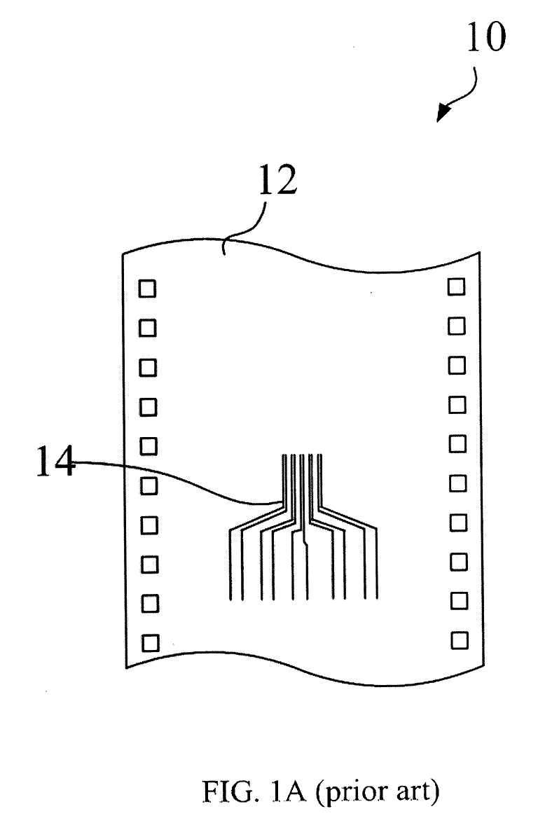

FIG. 1B is an enlarged view of the plurality of leads shown in FIG. 1A.

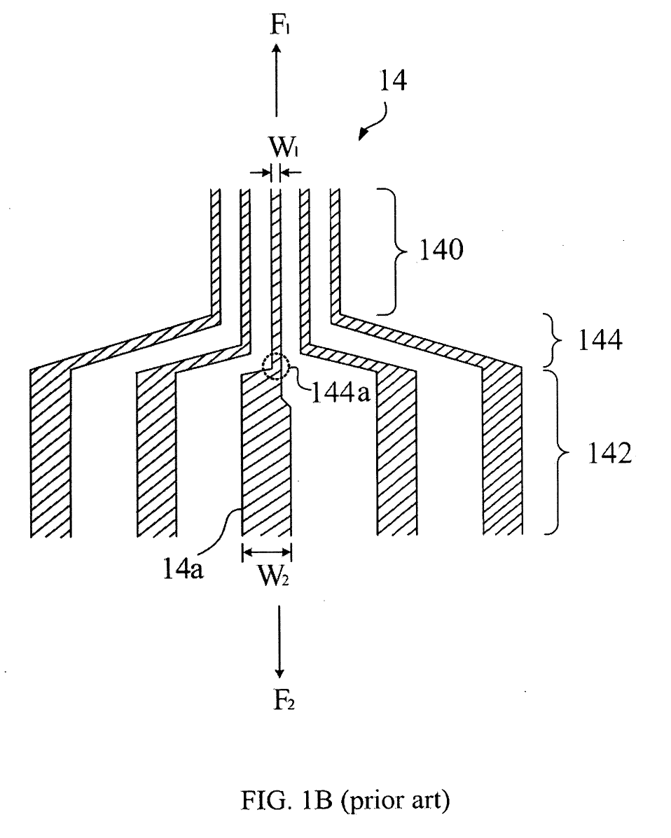

FIG. 2A is a schematic diagram of a flexible substrate according to the first preferred embodiment of the invention.

FIG. 2B is an enlarged view of the plurality of leads shown in FIG. 2A.

### DETAILED DESCRIPTION OF THE INVENTION

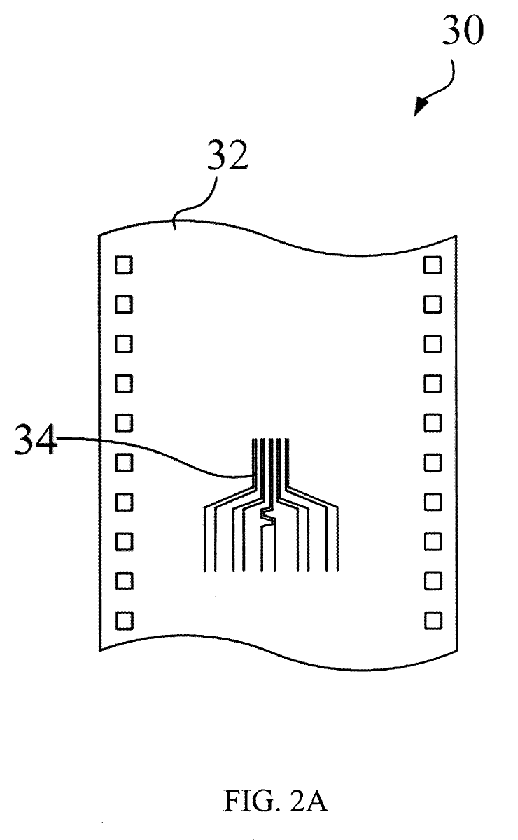

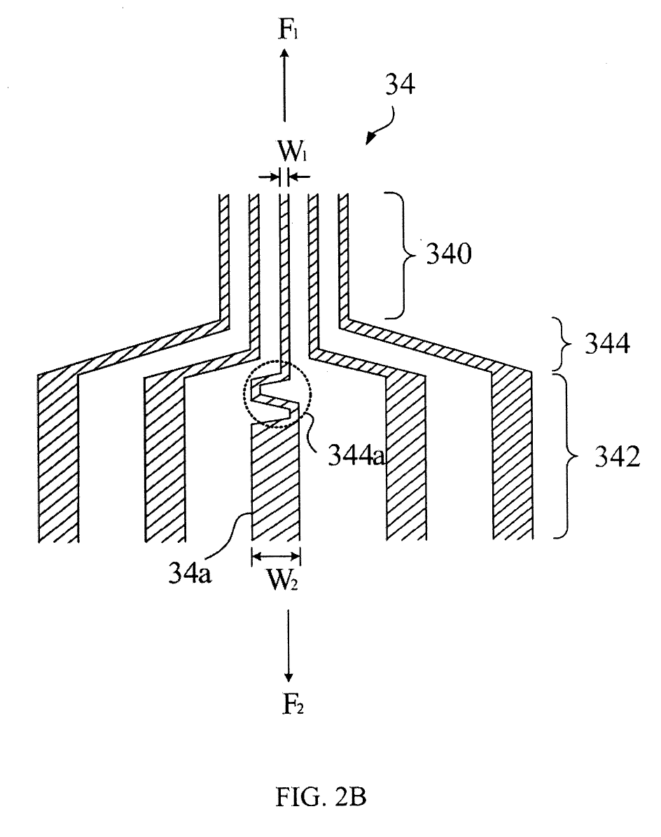

Referring to FIG. 2A and FIG. 2B, FIG. 2A is a schematic diagram of a flexible substrate 30 according to the first preferred embodiment of the invention, and FIG. 2B is an enlarged view of the plurality of leads 34 shown in FIG. 2A. As shown in FIG. 2A, the flexible substrate 30 includes a flexible insulating film 32 and a plurality of leads 34 formed on the flexible insulating film 32. As shown in FIG. 2B, each of the leads 34 includes a first portion 340, a second portion 342, and a connection portion 344 connecting the first portion 340 and the second portion 342. It should be noticed, the connection portion 344a of at least one lead 34a of the leads 34 is designed as crooked, such as a sawtooth shape, a corrugated shape, or a horseshoe shape, as shown in FIG. 2B. The first portion 340 of each of the leads 34 is to be bonded to a die (not shown), and the second portion 342 of each of the leads 34 is to provide with a bonding for an external device (not shown). Furthermore, for each of the leads 34, the width W₁ of the first portion 340 is less than the width W₂ of the second portion 342, as shown in FIG. 2B.

In the first preferred embodiment described above, when the first portion 340 of each of the leads 34 is pulled by a first force F₁, and the second portion 342 of each of the leads 34 is pulled by a second force F₂ opposite to the first force F₁, the at least one crooked connection portion 344a will be expanded, so as to prevent the lead 34a corresponding to the connection portion 344a from fracturing.

Compared with the prior art, the connection of at least one of the leads of the invention is designed as crooked. When the lead is pulled by a force, the at least one crooked connection portion will be expanded, so as to prevent the lead corresponding to the connection portion from fracturing.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A flexible substrate, comprising:
a flexible insulating film having an upper surface; and
a plurality of leads, formed on the upper surface of the flexible insulating film, each of the leads having a respective first portion, a respective second portion, and a respective connection portion connecting the first portion and the second portion, and at least one of the leads exhibiting a crooked shape at the connection portion thereof to provide a deformability to resist a tensile force once suffered by said one lead.

2. The flexible substrate of claim 1, wherein the first portion of each of the leads is to be bonded to a die.

3. The flexible substrate of claim 1, wherein the second portion of each of the leads is to provide with a bonding for an external device.

4. The flexible substrate of claim 1, wherein for each of the leads, the width of the first portion is less than that of the second portion.

5. The flexible substrate of claim 1, wherein at least one of the leads exhibits a sawtooth shape at the connection portion thereof.

6. The flexible substrate of claim 1, wherein at least one of the leads exhibits a corrugated shape at the connection portion thereof.

7. The flexible substrate of claim 1, wherein at least one of the leads exhibits a horseshoe shape at the connection portion thereof.
